(19) United States
(12) Patent Application Publication
(10) Pub. No.: US 2009/0153368 A1
(43) Pub. Date: Jun. 18, 2009

(54) TACTILE INPUT/OUTPUT DEVICE AND DRIVING METHOD THEREOF

(76) Inventors: Ji-Hye HUR, Suwon-si (KR); Jong-Rim LEE, Seoul (KR); Ki-Uk KIM, Suwon-si (KR); Chul-Jin KIM, Yongin-si (KR); June-Hyeok IM, Seoul (KR); Chul-Hyun PARK, Suwon-si (KR); Sae-Rome KIM, Seoul (KR)

Correspondence Address: CHA & REITER, LLC, 210 ROUTE 4 EAST STE 103, PARAMUS, NJ, 07652, US

(21) Appl. No.: 12/333,430

(22) Filed: Dec. 12, 2008

(30) Foreign Application Priority Data
Dec. 12, 2007 (KR) 10-2007-0129305

(51) Int. Cl. H03K 17/94; H01L 41/113

(52) U.S. Cl. 341/20; 310/338

(57) ABSTRACT

A tactile input/output device and a driving method thereof are provided. The device includes at least one input end, at least one output end, and a controller. The input end includes a plurality of input cells arranged at regular intervals. The output end includes a plurality of output cells arranged at regular intervals. The controller senses an input signal of the input end and controls the output end to generate a corresponding output signal. The input end and the output end are installed to form one array with being separated. The input cell and the output cell are arranged so that they do not overlap with each other.

### CLAIM OF PRIORITY

This application claims priority of an earlier Korean Patent Application filed in the Korean Intellectual Property Office on Dec. 12, 2007 and assigned Serial No. 10-2007-0129305, the contents of which are herein incorporated by reference.

### BACKGROUND OF THE INVENTION

1. Field of the Invention

The present invention relates generally to a tactile input/output device used as data input/output means in various electronic equipments. More particularly, the present invention relates to a tactile input/output device that enables variety of tactile output responsive to input, and a driving method thereof.

2. Description of the Related Art

In general, many types of electronic equipments with portable terminals include displays as data output means. The display devices evolve from early black/white Liquid Crystal Displays (LCDs) to high-definition color LCD modules with several hundreds of thousands to a few millions pixels. This is a reflection of trend for miniaturization, lightness, and slimness and simultaneously demanding a variety of functions. The displays display data such as general characters and videos such as still pictures, moving pictures, etc. to the users.

A recent market trend shows a data input/output device with a touch screen function. The data input/output device does not require separate data input means such as a key button, etc. and allows simultaneously enable input/output functions in one display device. Such a touch screen greatly reduces user's tactile sensation during data input compared to a general mechanical type (i.e., metal dome type) key button. Thus, in recent years, the advent of a tactile input/output device with a driver for generating a vibration has been made. The tactile input/output device is configured to provide a little vibration to a user at a time the user touches a desired screen, thus eliminating a slight feeling of aversion to a plane touch.

Most of conventional vibration tactile display devices are based on a scheme of vibrating the whole body using a small sized motor, such as a vibration tactile mouse, a vibration mode of a portable phone, etc. In a tactile feedback system, a tactile input unit and a tactile output unit are completely separated from each other or only a method of expressing a simple feedback for input identification exists.

FIG. 2 is a schematic diagram illustrating a tactile input/output device according to the conventional art. In FIG. 2, a tactile sensor input end 10 and a tactile display output end 20 are completely separated and independent from each other. However, there is a problem of causing erroneous operation and noise generation due to mutual interferences as an input cell 11 of the tactile sensor input terminal 10 and an output cell 21 of the output terminal 20 are configured to overlap with each other.

The above mentioned scheme of vibrating the whole device body using a small sized motor has been put on the market in recent years. However, this scheme limits an expression of tactile sensation that a user can feel with his/her fingertip and provides unsatisfactory effect. Also, a tactile input/output device of a type in which an input sensor attached to a vibration motor has a problem that it has a limitation in reducing a thickness and has poor durability.

Also, in the case of the using the same array address without separation of input/output, a control complexity increases and, because the extension of a sensor array leads to an increase in operation, a circuitry complexity increases. Further, as simply controlling only the input on/off switch information by a combination of X and Y-axes, a conventional sensing technology has a difficulty in applying to a variety of input/output schemes.

### SUMMARY OF THE INVENTION

An aspect of the present invention is to substantially solve at least the above problems and/or disadvantages and to provide at least the advantages below. Accordingly, one aspect of the present invention is to provide a tactile input/output device to enable a tactile output of various schemes in response to an input, and a driving method thereof.

Another aspect of the present invention is to provide a tactile input/output device realized to prevent noise and erroneous operation from being generated due to mutual interferences between respective input/output cells by separating and applying a tactile input end and output end, and a driving method thereof.

A further aspect of the present invention is to provide a tactile input/output device realized to reduce an amount of operation corresponding to a Y-axis value by, out of a simple X and Y structure, matching a range of a voltage value of only an X-axis to a coordinate, obtaining an X-axis value corresponding to a center value and a Z-axis value corresponding to a pressure value, and enabling the same sensing, and a driving method thereof.

According to one aspect of the present invention, a tactile input/output device includes at least one input end, at least one output end, and a controller. The input end includes a plurality of input cells arranged at regular intervals. The output end includes a plurality of output cells arranged at regular intervals. The controller senses an input signal of the input end and controls the output end to generate a corresponding output signal. The input end and the output end are installed to form one array with being separated. The input cell and the output cell are arranged in a position not overlapping with each other.

According to another aspect of the present invention, a method for driving a tactile input/output device includes at least one input end, at least one output end, and a controller. The input end includes a plurality of input cells arranged at regular intervals. The output end includes a plurality of output cells arranged at regular intervals. The controller senses an input signal of the input end and controls the output end to generate a corresponding output signal. The input end and the output end are installed to form one array with being separated. The input cell and the output cell are arranged in a position not overlapping with each other to operate separately from each other.

According to a further aspect of the present invention, a method for detecting an input signal of a tactile input/output device includes at least one input end, at least one output end, and a controller. The input end includes a plurality of input cells arranged at regular intervals. The output end includes a plurality of output cells arranged at regular intervals. The controller senses an input signal of the input end and controls the output end to generate a corresponding output signal. The input end uses a plurality of piezoelectric materials arranged in a column as input cells, electrically connects the piezoelectric materials with a variable resistor, reads a variation of the variable resistor depending on a voltage difference of the piezoelectric material that varies depending on an applied pressure, and detects an input signal of various types.

### BRIEF DESCRIPTION OF THE DRAWINGS

The above features and advantages of the present invention will become more apparent from the following detailed description when taken in conjunction with the accompanying drawings in which:

FIG. 1 is a perspective diagram illustrating a portable terminal applying a tactile input/output device according to an exemplary embodiment of the present invention;

FIG. 2 is a schematic diagram illustrating a construction of a tactile input/output device according to the conventional art;

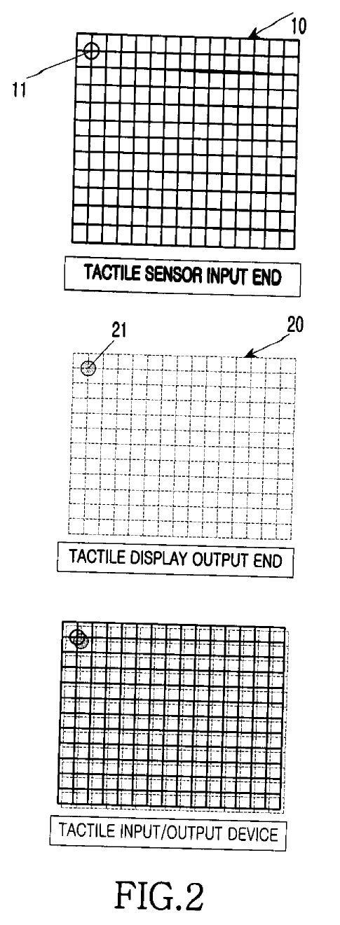

FIG. 3 is a schematic diagram illustrating a construction of a tactile input/output device according to an exemplary embodiment of the present invention;

FIG. 4 is a schematic side diagram illustrating a tactile input/output device according to an exemplary embodiment of the present invention;

FIG. 5 is a diagram illustrating various arrangements of tactile input/output cells according to another exemplary embodiment of the present invention;

FIG. 6 is a block diagram illustrating a construction of a tactile input/output device according to an exemplary embodiment of the present invention; and

FIG. 7 is a diagram illustrating a construction of a tactile input device according to an exemplary embodiment of the present invention.

### DETAILED DESCRIPTION OF THE INVENTION

Now, embodiments of the present invention will be described herein below with reference to the accompanying drawings. For the purposes of clarity and simplicity, well-known functions or constructions are not described in detail as they would obscure the invention in unnecessary detail.

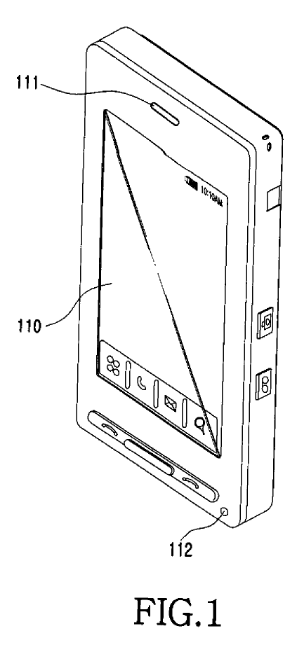

FIG. 1 is a perspective diagram illustrating a portable terminal employing a tactile input/output device according to an exemplary embodiment of the present invention. Note that the inventive tactile input/output device is applicable to a portable terminal and other electronic equipments with display devices known to artisian.

As shown in FIG. 1, a portable terminal 100 has a display device 110, and can input program execution, numerals, characters, symbols, etc. displayed on the display device 110, by a touch operation without using traditional key buttons. A speaker 111, which is a receiver, is installed above the display device 110. A microphone 112, which is a transmitter, is installed under the display device 110.

The display device 110 displays and receives input data on a screen and output a variety of tactile sensation depending on an input scheme. For example, when a pressure scheme is applied, if a user lightly touches a corresponding icon, a gentle vibration can be output to the user, and, in response to a harder touch, a stronger vibration can be output. Note that various input schemes can be used and, for example, a light intensity and a pressure can be used. Also, various output schemes can be implemented according to the teachings of the preset invention and, for example, an output scheme of generating varying level of temperature, generating a physical force such as a friction force, an electrostatic force, a magnetic force and other known sensation known to artisians.

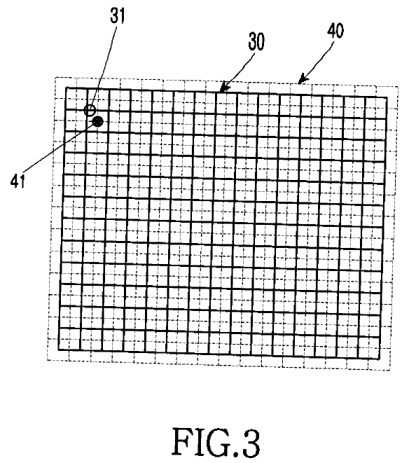

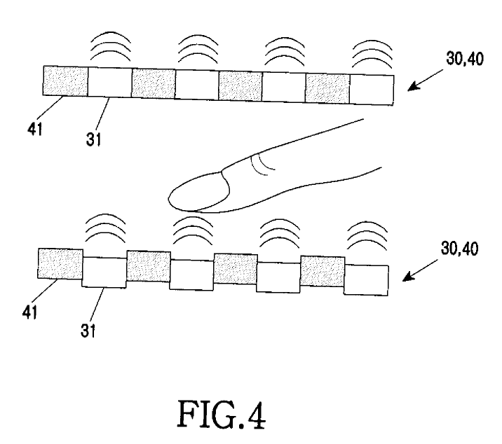

FIG. 3 is a schematic diagram illustrating the construction of a tactile input/output device according to an exemplary embodiment of the present invention. FIG. 4 is a schematic side diagram illustrating a tactile input/output device according to an exemplary embodiment of the present invention.

As shown in FIGS. 3 and 4, a tactile input/output device according to an exemplary embodiment of the present invention includes an input end 30 and an output end 40 independent from each other. The input end 30 includes a plurality of separate input cells 31. The output end 40 includes a plurality of separate output cells 41.

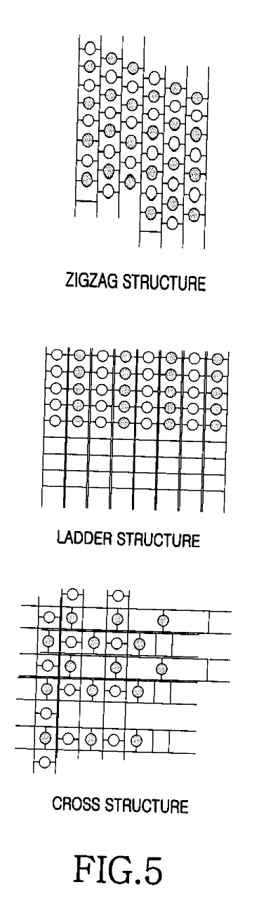

According to an exemplary embodiment of the present invention, although the input end 30 and output end 40 are constructed and combined together, the input cell 31 and output cell 41 do not overlap with each other. That is, the input cell 31 is disposed between neighboring output cells 41, and the output cell 41 is disposed in a unit space of a neighboring input cell 31. This arrangement structure optimally reduces a thickness of the tactile input/output device, increases durability of each cell, and suppresses generation of noise due to mutual interference. The input end 30 and the output end 40 can independently act as an input sensor and an output sensor, respectively. Thus, the output end 40 can operate independently and can express a feedback for an operation of the input end 30. For example, with generating tactile sensation using a physical force such as a friction force and an electrostatic force, the output end 40 receives simultaneously a signal from the input end 30. The output end 40 may express a different tactile sensation according to a button input from the input end 30. The conventional scheme has a problem that it has a limitation in reducing a thickness since the input end and the output end are configured to overlap with each other in order to simultaneously implement the input end 30 and the output end 40. However, the present invention provides that the input end 30 and the output end 40 are arranged closely in a line and can reduce the thickness. Also, the present invention provides satisfactorily an expression of tactile sensation that a user can feel with his/her fingertip. Thus, it is possible to independently and effectively implement the input end and the output end. Also, it is possible to promote their own flexibilities and to equip with a thin sensor where the input end and the output end can operate independently from each other on an object having a curve because of applying a cell structure of a long ladder shape of FIG. 5 using flexible materials such as a polymer and a Flexible Printed Circuit (FPC) and materials required to manufacture small-sized sensors such as a piezoelectric element, etc.

FIG. 5 is a diagram illustrating various arrangements of tactile input/output ends according to another exemplary embodiment of the present invention. As shown, the tactile input/output ends can employ a diversity of sequential arrangements such as a zigzag arrangement, a ladder shaped arrangement, a cross arrangement, etc. That is, the respective input cell and output cell are arranged in alternate sequence. The input cell and output cell can be formed to have a line ladder shaped structure beyond a conventional cross structure with X and Y-axes. This structure can promote relatively a faster output in response to input.

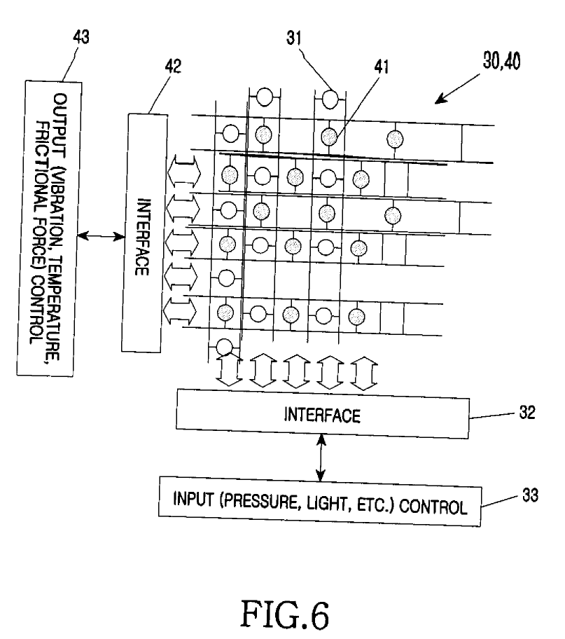

FIG. 6 is a block diagram illustrating the construction of a tactile input/output device according to the exemplary embodiment of the present invention. As shown, an input end 30 and an output end 40 of the tactile input/output device have a cross structure. Each input cell 31 of the input end 30 and each output cell 41 of the output end 40 do not overlap with each other and are configured to have a cross structure.

Each input cell 31 of the input end 30 electrically connects with an input controller 33 through an interface 32 (e.g., a multiplexer). Each output cell 41 of the output end 40 electrically connects with an output controller 43 through an interface 42. In an alternate embodiment, the input controller 33 and output controller 43 may be integrated as a single controller. If a control signal is sensed in response to an input, the controller drives a predetermined driver (not shown) such as an output vibration generator, etc., controlling an output.

Although described later, the controller can variously control an output scheme depending on the type of input signal. For example, the controller controls the intensity of a vibration output depending on an intensity of a pressure input, thus being capable of providing different levels of intensities of vibration to a user.

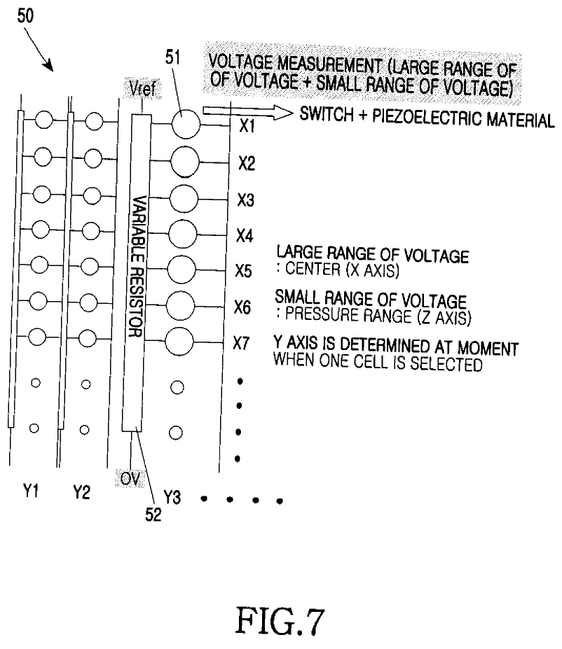

FIG. 7 is a diagram illustrating the construction of a tactile input device according to another exemplary embodiment of the present invention. As shown, the tactile input device includes a plurality of input ends (Y1, Y2, Y3 . . . ) arranged in column. Each input end has a plurality of input cells 51 arranged at regular intervals. The input cells 51 can be of piezoelectric material, for example, PieZoelectric Transducer (PZT) using a variation of a voltage difference responsive to a pressure, PolyVinyliDene Fluoride (PVDF), etc. The input cells 51 electrically connect to a variable resistor 52. The input cell 51 each can be matched to a coordinate value as an X-axis. The voltage difference generated by a pressure applied to the piezoelectric material is relatively less than a voltage difference generated by resistance and thus, this feature is used. A conventional tactile display device senses each signal line of an X-axis and a Y-axis in sequence to generate a coordinate (X, Y). However, according to the present invention, only Y-axis value is sensed to determine a signal variation in a cell. That is, it is determined what number of a signal line is sensed by scanning a Y-axis. Then, an X-axis value and a Z-axis value are obtained using only voltage information obtained from the Y-axis. Here, a tactile display device acts as a switch when pressing a piezoelectric material in signal information of the Y-axis signal line. A voltage difference or a current difference according to a variable resistor is changed and an X-axis corresponding to a resistance value at the time is obtained. Also, a small voltage difference is generated when applying a pressure to the piezoelectric material or a dielectric. The small voltage difference is converted into Z-position and thereby attaining the Z-axis value. In other words, the tactile display device recognizes the Y-axis value according to the presence of Y-axis signal. The X-value is obtained using a relatively large voltage difference or current difference when switched on by the piezoelectric material or the dielectric. The Z-value is obtained using a relatively small voltage difference or phase difference of the voltage. The voltage may be used in an AC, a DC or a combination thereof. For example, if a user applies pressure to a predetermined position on a tactile display device, a Y-axis is determined with only the selected position and, by matching a range of a voltage value extracted from Y-axis, X-axis value and Z-axis value corresponding to a pressure value are obtained, thus making the same sensing possible. That is, depending on a resistance value of the variable resistor variable due to a voltage difference of corresponding piezoelectric material, the controller (i.e., the output controller) can control an output generator such as a vibration generator (not shown) to generate a vibration of an intensity corresponding to a preset resistance value.

As described above, the teachings of the present invention has an advantage of being capable of increasing a contact sensitivity and making more accurate signal sensing possible by reducing a cell thickness, increasing durability of each cell, and reducing a noise caused by mutual interferences through separation between an input cell of a tactile input end and an output cell of a tactile output end. Also, an exemplary embodiment of the present invention has an advantage of, when an input cell and an output cell are attached to each other, reducing the number of times of a repeated switching operation requiring switching off the output cell so as to switch on the input cell, thereby being capable of increasing a response speed and simplifying a complex control circuit. Further, when an input and output are attached to each other, only a simple input touch can be sensed. However, when the two are separated, various intensities and levels of inputs (i.e., pressure intensities, light intensities, etc.) can be sensed. Moreover, unlike a conventional array sensing all of X and Y-axes and then recognizing a position by a combination thereof, an exemplary embodiment of the present invention has an advantage of, by matching a range of a voltage value of only an X-axis to a coordinate, obtaining an X-axis value corresponding to a center value and a Z-axis value corresponding to a pressure value, thus making the same sensing possible while reducing an amount of operation corresponding to a Y-axis value.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A tactile input/output device comprising:
at least one input end comprising a plurality of input cells arranged at regular intervals;
at least one output end comprising a plurality of output cells arranged at regular intervals; and
a controller for sensing an input signal of the at least one input end and controlling the at least one output end to generate a corresponding output signal,
wherein the at least one input end and the at least one output end are installed to form one array with being separated, and
wherein the input cell and the output cell do not overlap with each other.

2. The device of claim 1, wherein the input cell and output cell are positioned in alternate sequence.

3. The device of claim 2, wherein the at least one input end and the at least one output end are arranged to overlap with each other in a column direction.

4. The device of claim 2, wherein the at least one input end and the at least one output end are arranged to cross at right angles with each other.

5. The device of claim 1, wherein the at least one input end and the at least one output end are arranged to alternate with each other in the same direction or in a different direction.

6. The device of claim 1, wherein the at least one input end is arranged in a line in a column direction.

7. The device of claim 6, wherein the input cell of the at least one input end uses a plurality of piezoelectric materials whose voltage differences are variable depending on a pressure degree of activation, and senses the input signal by a variation of a variable resistor electrically connecting the piezoelectric material.

8. The device of claim 7, wherein the variable resistance value is set such that a voltage difference generated by the piezoelectric material is relatively less than a voltage difference generated by the resistor.

9. The device of claim 8, wherein the piezoelectric material is one of PieZoelectric Transducer (PZT) and PolyVinyliDene Fluoride (PVDF).

10. The device of claim 1, further comprising an output generator operated by the controller depending on the output signal of the at least one output end.

11. The device of claim 1, wherein the output generator is one of a vibration generator, a physical force generator, and a temperature generator, or a combination thereof.

12. The device of claim 9, wherein the controller controls the output generator to generate various intensities of a vibration, a contact force, or temperature variation in response to the input signal of the at least one input end.

13. A method for driving a tactile input/output device, comprising:
providing at least one input end comprising a plurality of input cells arranged at regular intervals;
providing at least one output end comprising a plurality of output cells arranged at regular intervals; and
providing a controller for controlling the at least one input end and the at least one output end,
wherein the at least one input end and the at least one output end are installed to form one array, and
wherein the input cell and the output cell do not overlap from each other.

14. The method of claim 13, wherein the controller controls the at least one input end and the at least one output end separately from each other.

15. The method of claim 14, wherein the controller senses an input signal of the at least one input end and controls the at least one output end to generate a corresponding output signal.

16. The method of claim 15, further providing an output generator coupled to the at least one output to operate depending on an output signal, and
wherein the controller variously controls the output generator in response to the input signal of the at least one input end.

17. The method of claim 16, wherein the output generator is one of a vibration generator, a physical force generator, and a temperature generator, or a combination thereof.

18. The method of claim 17, wherein the controller controls the output generator to generate various intensities of a vibration, a contact force, or temperature variations in response to the input signal of the input end.

19. A method for detecting an input signal of a tactile input/output device, comprising:
providing at least one input end comprising a plurality of input cells arranged at regular intervals;
providing at least one output end comprising a plurality of output cells arranged at regular intervals; and
providing a controller for controlling the input end and the output end,
wherein the at least one input end uses a plurality of piezoelectric materials arranged in a column as input cells, electrically connects the piezoelectric materials with a variable resistor, reads a variation of the variable resistor depending on a voltage difference of the piezoelectric material that varies depending on an applied pressure, and detects an input signal of various types.

20. The method of claim 19, wherein the variable resistance value is such that a voltage difference generated by the piezoelectric material is relatively less than a voltage difference generated by the resistor.

21. The method of claim 20, wherein the piezoelectric material is one of PieZoelectric Transducer (PZT) and PolyVinyliDene Fluoride (PVDF).

22. The method of claim 19, wherein the at least one input end is arranged in a regular sequence in a column direction and forms a Y-axis.
